(19) United States
(12) Patent Application Publication
(10) Pub. No.: US 2023/0363153 A1
(43) Pub. Date: Nov. 9, 2023

(54) NOR-TYPE MEMORY DEVICE, METHOD OF MANUFACTURING NOR-TYPE MEMORY DEVICE, AND ELECTRONIC APPARATUS INCLUDING MEMORY DEVICE

(71) Applicant: INSTITUTE OF MICROELECTRONICS, CHINESE ACADEMY OF SCIENCES, Beijing (CN)

(72) Inventor: Huilong Zhu, Poughkeepsie, NY (US)

(21) Appl. No.: 18/115,227

(22) Filed: Feb. 28, 2023

(30) Foreign Application Priority Data
May 6, 2022 (CN) 202210489704.4

(51) Int. Cl. H10B 41/27; H10B 43/27; H10B 51/20

(52) U.S. Cl. CPC H10B 41/27; H10B 43/27; H10B 51/20

(57) ABSTRACT

Disclosed are a NOR-type memory device, a method of manufacturing the NOR-type memory device, and an electronic apparatus. The NOR-type memory device includes a plurality of device layers. Each device layer includes a first source/drain region and a second source/drain region at opposite ends of the device layer in a vertical direction, and a channel region between the first source/drain region and the second source/drain region; and a gate stack that extends vertically with respect to the substrate. The gate stack includes a gate conductor layer and a memory functional layer disposed between the gate conductor layer and the device layer. A memory cell is defined at an intersection of the gate stack and the device layer. The memory functional layer includes a first layer having a plurality of portions that correspond to the plurality of device layers respectively and are discontinuous with each other in the vertical direction.

### CROSS-REFERENCE TO RELATED APPLICATIONS

This application is claims priority to Chinese Application No. 202210489704.4 filed on May 6, 2022, which is incorporated herein by reference in its entirety.

### TECHNICAL FIELD

The present disclosure relates to the field of semiconductors, and more particularly, to a NOR-type memory device, a method of manufacturing the NOR-type memory device, and an electronic apparatus including the memory device.

### BACKGROUND

In a planar device such as a Metal Oxide Semiconductor Field Effect Transistor (MOSFET), a source, a gate and a drain are arranged in a direction substantially parallel to a substrate surface. Due to such an arrangement, the planar device is difficult to be further scaled down. In contrast, in a vertical device, a source, a gate and a drain are arranged in a direction substantially perpendicular to a substrate surface. As a result, the vertical device is easier to be scaled down compared to the planar device.

Vertical devices may be stacked to increase the integration density. It is desired to reduce mutual interference between devices stacked on each other.

### SUMMARY

In view of the above, the present disclosure aims to provide, among others, a NOR-type memory device with an improved performance, a method of manufacturing the NOR-type memory device, and an electronic apparatus including the memory device.

According to an aspect of the present disclosure, there is provided a NOR-type memory device, including: a plurality of device layers stacked on a substrate, wherein each of the plurality of device layers includes a first source/drain region and a second source/drain region at opposite ends of the device layer in a vertical direction, and a channel region between the first source/drain region and the second source/drain region in the vertical direction; and a gate stack that extends vertically with respect to the substrate to pass through each of the plurality of device layers, wherein the gate stack includes a gate conductor layer and a memory functional layer disposed between the gate conductor layer and the device layer, and a memory cell is defined at an intersection of the gate stack and the device layer, wherein the memory functional layer includes a first layer, and the first layer has a plurality of portions that correspond to the plurality of device layers respectively and are discontinuous with each other in the vertical direction.

According to another aspect of the present disclosure, there is provided a method of manufacturing a NOR-type memory device, including: alternately disposing a plurality of device layers and a plurality of isolation layers on a substrate, so that each of the plurality of device layers is located between isolation layers in a vertical direction; forming a processing channel that extends vertically with respect to the substrate to pass through each of the plurality of device layers and each of the plurality of isolation layers; selectively etching the device layer through the processing channel, so that the device layer is transversely recessed with respect to the isolation layer; forming a memory functional layer on a sidewall of the processing channel, wherein the memory functional layer includes a first layer, and the first layer has a plurality of portions, wherein each portion of the first layer is located between respective isolations layers and the plurality of portions are discontinuous with each other in the vertical direction; and forming a gate conductor layer in the processing channel with the sidewall on which the memory functional layer is formed, wherein a corresponding memory cell is defined at a position where the gate conductor layer intersects a corresponding device layer via the memory functional layer.

According to another aspect of the present disclosure, there is provided an electronic apparatus including the NOR-type memory device described above.

According to embodiments of the present disclosure, in the NOR-type memory device, at least one layer (a first layer, especially a conductive layer) in the memory functional layer is separated apart between memory cells, so that mutual interference between memory cells may be reduced. In addition, a stack of single crystal material may be used as a building block to build a three-dimensional (3D) NOR-type memory device. Therefore, when a plurality of memory cells are stacked, an increase of resistance may be suppressed.

### BRIEF DESCRIPTION OF THE DRAWINGS

The above and other objects, features, and advantages of the present disclosure will become more apparent from following descriptions on embodiments thereof with reference to attached drawings, in which:

FIGS. 1 to 15(c) are schematic diagrams showing some stages in a process of manufacturing a NOR-type memory device according to an embodiment of the present disclosure;

FIGS. 16(a) and 16(b) are schematic diagrams showing some stages in a process of manufacturing a NOR-type memory device according to another embodiment of the present disclosure;

FIG. 17 is a schematic diagram showing some stages in a process of manufacturing a NOR-type memory device according to another embodiment of the present disclosure;

FIG. 18 is a schematic diagram showing some stages in a process of manufacturing a NOR-type memory device according to another embodiment of the present disclosure;

FIG. 19 is a schematic diagram showing some stages in a process of manufacturing a NOR-type memory device according to another embodiment of the present disclosure;

FIG. 20 is a schematic diagram showing some stages in a process of manufacturing a NOR-type memory device according to another embodiment of the present disclosure;

FIG. 21 schematically shows an equivalent circuit diagram of a NOR-type memory device according to an embodiment of the present disclosure;

FIGS. 22(a) to 27 are schematic diagrams showing some stages in a process of manufacturing a NOR-type memory device according to another embodiment of the present disclosure;

FIG. 28 is a schematic diagram showing some stages in a process of manufacturing a NOR-type memory device according to another embodiment of the present disclosure,

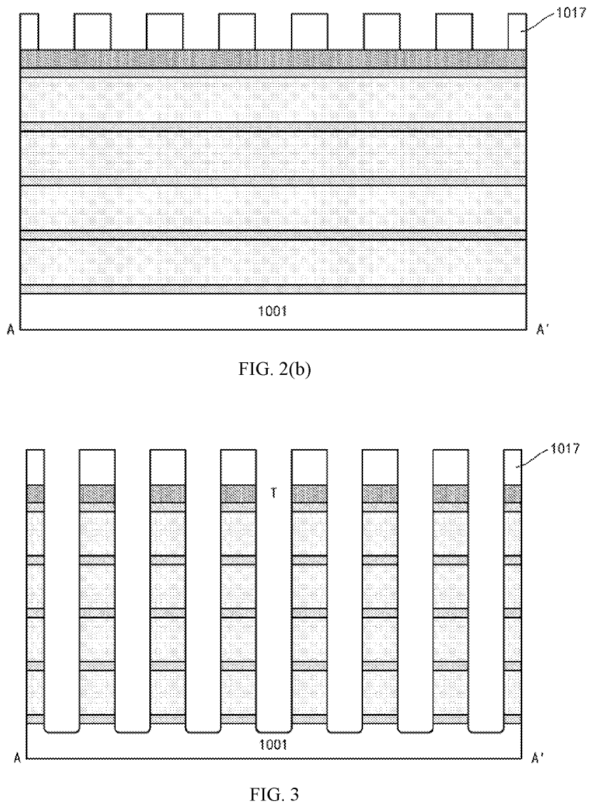

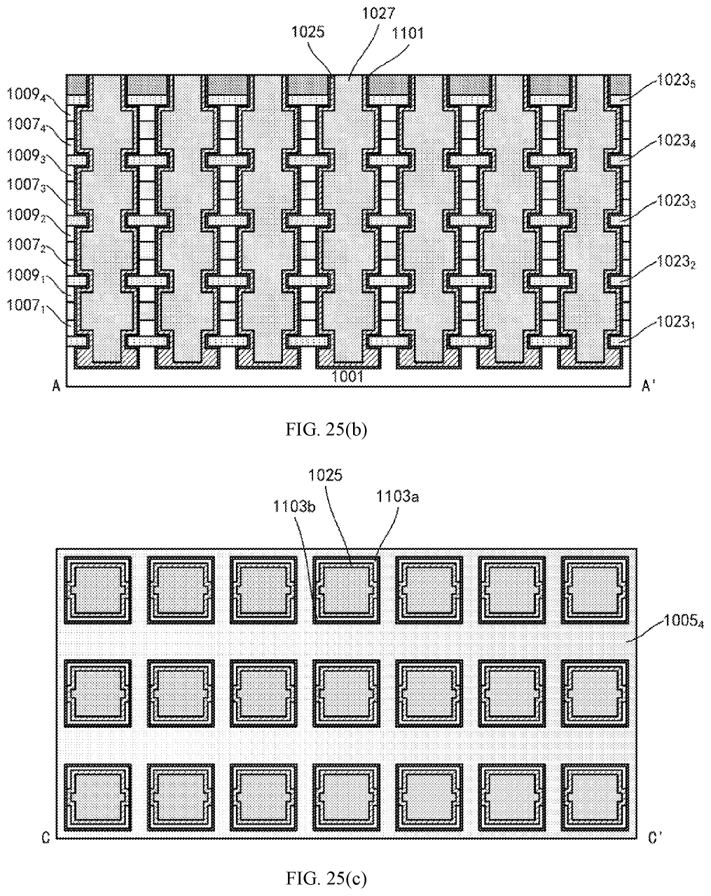

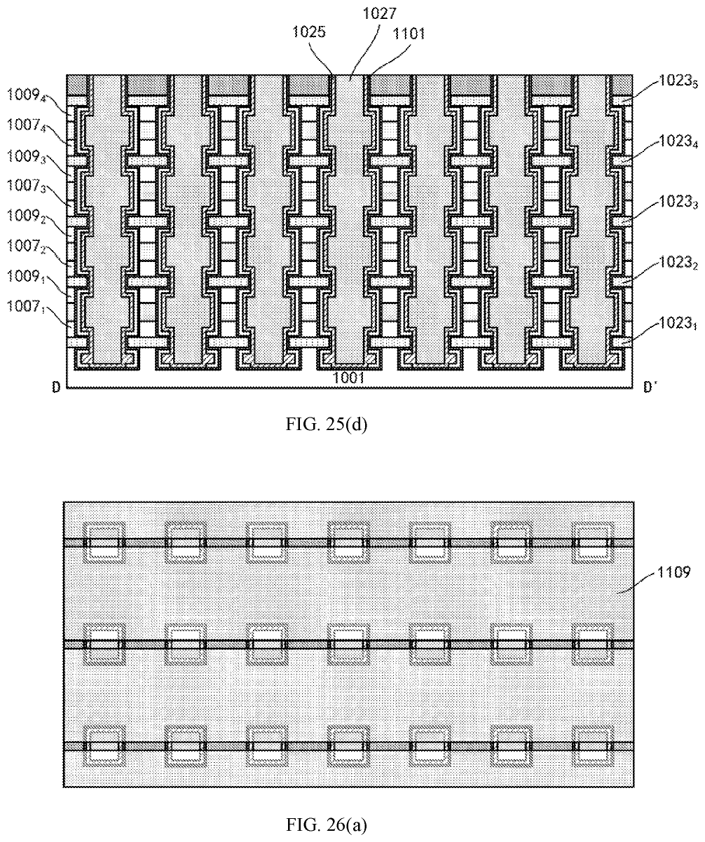

wherein FIGS. 2(a), 11(a), 15(a), 16(a), 22(a), 24(a), 25(a), 26(a), and 27 are top views, FIG. 2(a) shows positions of line AA′ and line BB′, and FIG. 25(a) shows a position of line DD′;

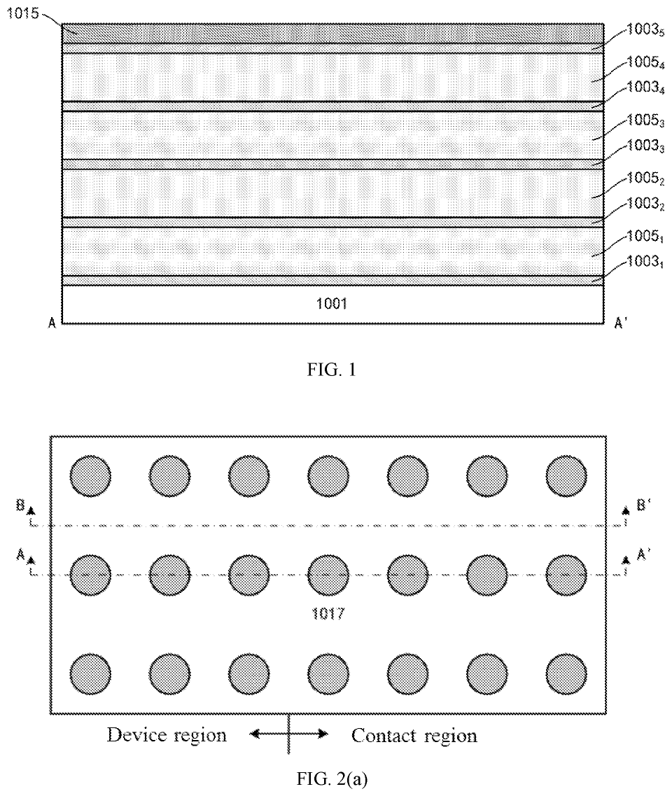

FIGS. 1, 2(b), 3 to 7, 8(a), 8(b), 9, 10, 11(b), 12(a), 13(a), 14(a), 15(b), 16(b), 20, 22(b), 23(a), 24(b), 25(b), and 26(b) are cross-sectional views taken along line AA′, and FIG. 23(a) shows a position of line CC′;

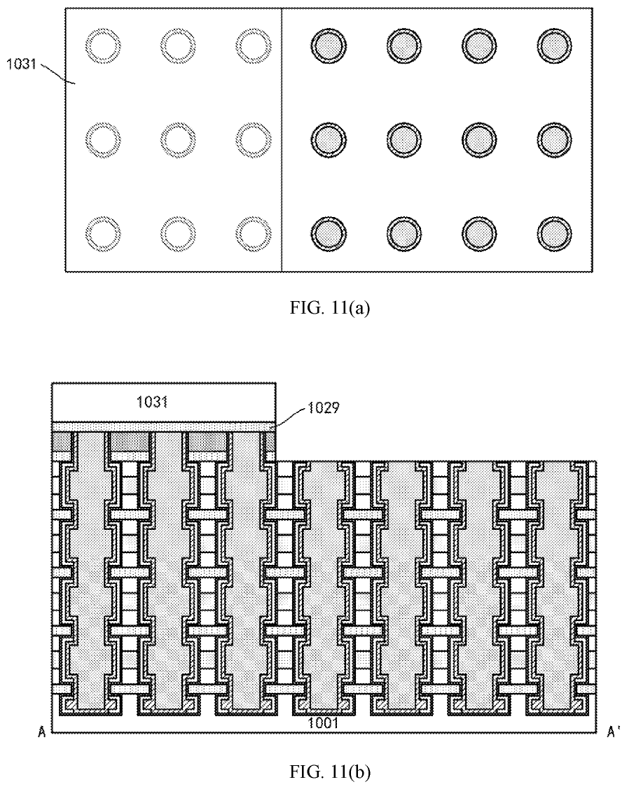

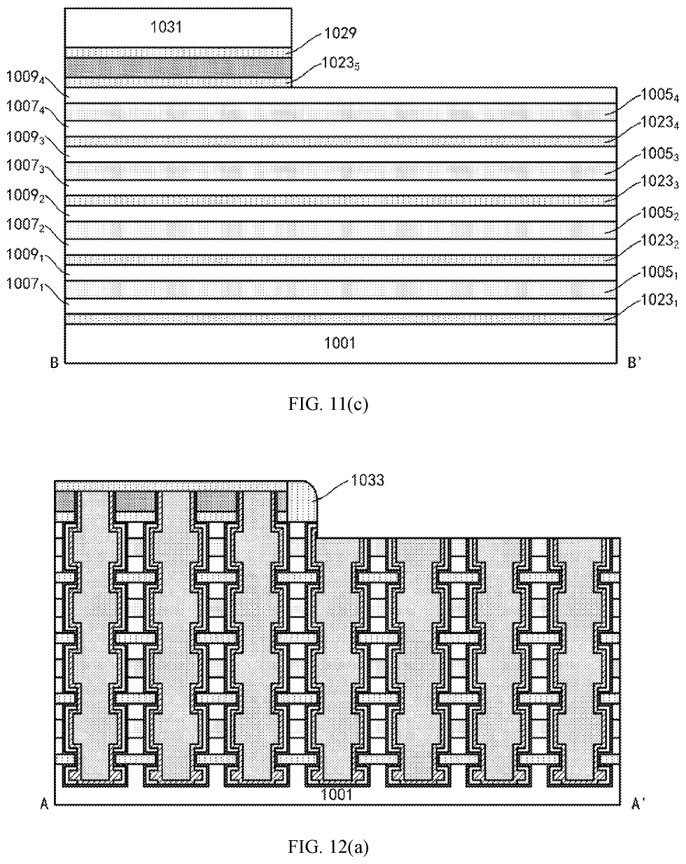

FIGS. 11(c), 12(b), 13(b), 14(b), 15(c), and 17 to 19 are cross-sectional views taken along line BB′;

FIGS. 23(b), 24(c), 25(c), 26(c), and 28 are cross-sectional views taken along line CC′;

FIG. 25(d) is a cross-sectional view taken along line DD′.

Throughout the drawings, the same or similar reference numbers denote the same or similar elements.

### DETAILED DESCRIPTION OF EMBODIMENTS

Hereinafter, descriptions are given with reference to embodiments shown in the attached drawings. However, it is to be understood that these descriptions are illustrative and not intended to limit the present disclosure. Further, in the following, known structures and technologies are not described to avoid obscuring the present disclosure unnecessarily.

In the drawings, various structures according to the embodiments are schematically shown. However, they are not drawn to scale, and some features may be enlarged while some features may be omitted for sake of clarity. Moreover, shapes and relative sizes and positions of regions and layers shown in the drawings are also illustrative, and deviations may occur due to manufacture tolerances and technique limitations in practice. Those skilled in the art may also devise regions/layers of other different shapes, sizes, and relative positions as desired in practice.

In the context of the present disclosure, when a layer/element is recited as being “on” a further layer/element, the layer/element may be disposed directly on the further layer/element, or otherwise there may be an intervening layer/element interposed therebetween. Further, if a layer/element is “on” a further layer/element in an orientation, then the layer/element may be “under” the further layer/element when the orientation is turned.

A memory device according to an embodiment of the present disclosure is based on a vertical device. The vertical device may include an active region arranged on a substrate in a vertical direction (a direction substantially perpendicular to a surface of the substrate). The active region includes source/drain regions at upper and lower ends of the active region and a channel region between the source/drain regions. A conductive channel may be formed between the source/drain regions through the channel region. In the active region, the source/drain regions and the channel region may be defined by, for example, a doping concentration.

According to an embodiment of the present disclosure, the active region may be defined by a device layer on the substrate. For example, the device layer may be a semiconductor material layer, the source/drain regions may be respectively formed at opposite ends of the semiconductor material layer in the vertical direction, and the channel region may be formed in a middle portion of the semiconductor material layer in the vertical direction. Alternatively, a (annular) nanosheet layer may be grown on a sidewall of the semiconductor material layer (also referred as a “base layer”), the source/drain regions may be respectively formed at opposite ends of the nanosheet layer in the vertical direction, and the channel region may be formed in a middle portion of the nanosheet layer in the vertical direction. A gate stack may extend through the device layer, so that the active region may surround a periphery of the gate stack. Here, the gate stack may include a memory functional layer (including, for example, a charge trapping layer or a floating gate layer), so as to achieve a memory function. In this way, the gate stack is cooperated with an active region opposite to the gate stack, so as to define a memory cell. Here, the memory cell may be a flash memory cell.

A plurality of gate stacks may be arranged to pass through the device layer, so as to define a plurality of memory cells at intersections of the plurality of gate stacks and the device layer. In a plane where the device layer is located, these memory cells are arranged into an array (for example, generally, a two-dimensional array arranged in rows and columns) corresponding to the plurality of gate stacks.

Since the vertical device is easy to be stacked, the memory device according to an embodiment of the present disclosure may be a three-dimensional (3D) array. Specifically, a plurality of such device layers may be arranged in the vertical direction. The gate stack may extend vertically to pass through the plurality of device layers. In this way, for a single gate stack, it intersects the plurality of device layers stacked in the vertical direction to define a plurality of memory cells stacked in the vertical direction.

A first layer (at least the first layer in the case of a plurality of layers), especially a conductive layer, in the memory functional layer may have a discontinuous configuration between memory cells. For example, the first layer may have a plurality of portions that correspond to the plurality of device layers respectively and are discontinuous with each other in the vertical direction. Such discontinuous configuration may reduce mutual interference between memory cells. As described below, the first layer may be formed in a self-aligned manner. Specifically, each portion of the first layer may be self-aligned with the corresponding device layer.

It is not necessary for all layers in the memory functional layer to have a discontinuous configuration. For example, at least a second layer other than the first layer, especially an insulating layer, may extend continuously in the vertical direction.

In a NOR (NOT OR)-type memory device, each memory cell may be connected to a common source line. In view of such configuration, two adjacent memory cells in the vertical direction may share the same source line connection, so as to save wirings. For example, each of the two adjacent memory cells may have a near end (i.e., an end close to the other of the two adjacent memory cells) and a far end (i.e., an end away from the other of the two adjacent memory cells). For each of the two adjacent memory cells, the source/drain region at the near end of the memory cell is used as a source region and thus is electrically connected to a source line, for example, through a common contact portion; and the source/drain region at the far end of the memory cell is used as a drain region and may be connected to a bit line. The drain regions of the two adjacent memory cells may be connected to different bit lines respectively.

The device layer may be formed by epitaxial growth and may be made of a single crystal semiconductor material. Compared with a conventional process of forming a plurality of gate stacks stacked on each other and then forming a vertical active region which passes through these gate stacks, it is easier to form an active region (especially the channel region) of single crystal in the present disclosure.

The device layer may be doped in situ and a doping characteristic of the device layer may be defined during growth. In addition, a doping of the source/drain region may be formed by diffusion. For example, solid phase dopant source layers (the solid phase dopant source layer may also be used as an isolation layer between memory cells) may be arranged at opposite ends of each device layer, and a dopant in the solid phase dopant source layer may be driven into the device layer (for example, the above-mentioned stack or the semiconductor layer grown on the sidewall of the stack), so as to form the source/drain region. Accordingly, a doping distribution of the source/drain region and a doping distribution of the channel region may be adjusted separately, and a steep high source/drain doping may be formed.

When the source/drain region and the channel region are formed in the above-mentioned semiconductor layer, the semiconductor layer may be a bulk material, and thus the channel region is formed in the bulk material. In this case, the process is relatively simple. In addition, when the channel region is formed in the nanosheet layer, the semiconductor layer may be formed as a nanosheet or a nanowire, and thus the channel region is formed in the nanosheet or the nanowire (the memory cell becomes a nanosheet or nanowire device). In this case, good control of a short channel effect may be achieved. In addition, as described below, a Super Steep Retrograded Well (SSRW) may also be formed in the semiconductor layer, which helps to control the short channel effect.

Such vertical memory device may be manufactured as follows. Specifically, a plurality of device layers and a plurality of isolation layers (isolation layer may be a solid phase dopant source layer containing a dopant) may be alternately provided on the substrate, so that each device layer is located between isolation layers in the vertical direction. The device layer may be provided by epitaxial growth. During epitaxial growth, a position of the isolation layer may be defined by a sacrificial layer. The sacrificial layer may then be replaced by the isolation layer. In addition, in situ doping may be performed during epitaxial growth, so as to achieve a desired doping polarity and doping concentration.

A processing channel, which extends vertically with respect to the substrate to pass through each of the plurality of device layers, may be formed. In the processing channel, a sidewall of the sacrificial layer may be exposed, so that the sacrificial layer may be replaced by the isolation layer. Agate stack may be formed in the processing channel. In addition, when the isolation layer is the solid phase dopant source layer, the dopant may be driven from the isolation layer to opposite ends of the device layer by annealing, so as to form the source/drain region. The solid phase dopant source layer may be replaced by an isolation layer which does not intentionally contain a dopant.

The present disclosure may be presented in various forms, and some examples of which will be described below. In the following description, the selection of various materials is involved. In selecting the materials, etching selectivity is considered in addition to the function of the material (for example, a semiconductor material is used to form the active region, a dielectric material is used to form an electrical isolation, and a conductive material is used to form an electrode, an interconnection structure, etc.). In the following description, the required etching selectivity may or may not be indicated. It should be clear to those skilled in the art that when etching a certain material layer is mentioned below, if it is not mentioned that other layers are also etched or the drawing does not show that other layers are also etched, then this etching may be selective, and the material layer may have etching selectivity with respect to other layers exposed to the same etching recipe.

FIGS. 1 to 15(c) are schematic diagrams showing some stages in a process of manufacturing a NOR-type memory device according to an embodiment of the present disclosure.

As shown in FIG. 1, a substrate 1001 is provided. The substrate 1001 may be a substrate in any form, for example, but not limited to, a bulk semiconductor material substrate such as a bulk silicon (Si) substrate, a Semiconductor On Insulator (SOI) substrate, a compound semiconductor substrate such as an SiGe substrate, or the like. Hereinafter, the bulk Si substrate, such as a Si wafer, will be described by way of example for the convenience of description.

On the substrate 1001, a memory device, such as a NOR-type flash memory, may be formed as described below. A memory cell in the memory device may be an n-type device or a p-type device. Here, an n-type memory cell is described as an example. For this purpose, a p-type well may be formed in the substrate 1001. Therefore, the following description, in particular the description of a doping type, is for forming the n-type device. However, the present disclosure is not limited thereto.

On the substrate 1001, a sacrificial layer 1003₁ used to define the isolation layer and a device layer 1005₁ used to define an active region of the memory cell may be formed by, for example, epitaxial growth.

Each layer grown on the substrate 1001 may be a single crystal semiconductor layer. These layers may have a crystal interface or a doping concentration interface between each other because they are grown or doped separately.

The sacrificial layer 1003₁ may then be replaced by an isolation layer used to isolate the device from the substrate. A thickness of the sacrificial layer 1003₁ may correspond to a thickness of the isolation layer that is desired to be formed, for example, about 10 nm to 50 nm. According to a circuit design, the sacrificial layer 1003₁ may be omitted. The device layer 1005₁ may define the active region of the memory cell subsequently, and may have a thickness of about 40 nm to 300 nm.

These semiconductor layers may include various suitable semiconductor materials, for example, an element semiconductor material such as Si or Ge, a compound semiconductor material such as SiGe, etc. Considering the following process of replacing the sacrificial layer 1003₁ by the isolation layer, the sacrificial layer 1003₁ may have etching selectivity with respect to the device layer 1005₁. For example, the sacrificial layer 1003₁ may include SiGe (an atomic percentage of Ge, for example, is about 15% to 30%), and the device layer 1005₁ may include Si.

The device layer 1005₁ may be doped in situ when growing. For example, for the n-type device, a p-type doping may be performed, and a doping concentration may be, for example, about 1E17 cm⁻³ to 1E19 cm⁻³. Such doping may define a doping characteristic in the subsequently formed channel region, so as to adjust a threshold voltage (Vₜ) of the device, control the short channel effect, and the like. Here, the doping concentration may have a non-uniform distribution in the vertical direction, so as to optimize the device performance. For example, a concentration in a region close to the drain region (subsequently connected to the bit line) is relatively high to reduce the short channel effect, while a concentration in a region close to the source region (subsequently connected to the source line) is relatively low to reduce the channel resistance. This may be achieved by introducing different dosages of the dopant at different phases of growth.

In order to increase an integration density, a plurality of device layers may be provided. For example, device layers 1005₂, 1005₃, and 1005₄ may be provided on the device layer 1005₁ by epitaxial growth. Device layers are separated from each other by sacrificial layers 1003₂, 1003₃, and 1003₄, which are used to define the isolation layer. Although only four device layers are shown in FIG. 1, the present disclosure is not limited thereto. According to the circuit design, it is possible to omit the isolation layer between certain device layers. Each of the device layers 1005₂, 1005₃, and 1005₄ may have a same or similar thickness and/or material as a thickness and/or material of the device layer 1005₁, or may have different thicknesses and/or materials from the thickness and/or material of the device layer 1005₁. Here, for convenience of description only, it is assumed that each device layer has the same configuration.

On such layers formed on the substrate 1001, a hard mask layer 1015 may be provided to facilitate patterning. For example, the hard mask layer 1015 may include nitride (for example, silicon nitride). A thickness of the hard mask layer 1015 is about 50 nm to 200 nm.

It is also possible to provide a sacrificial layer 1003₅, which is used to define the isolation layer, between the hard mask layer 1015 and the device layer 1005₄. For sacrificial layers 1003₂ to 1003₅, reference may be made to the above description of sacrificial layer 1003₁.

In the following, on the one hand, a processing channel which may reach the sacrificial layer is desired, so as to replace the sacrificial layer by the isolation layer. On the other hand, it is desired to define a region used to form a gate. According to an embodiment of the present disclosure, the two aspects may be implemented in combination. Specifically, a gate region may be defined by the processing channel.

For example, as shown in FIGS. 2(a) and 2(b), a photoresist 1017 may be formed on the hard mask layer 1015. The photoresist 1017 may be patterned to have a plurality of openings by photolithography, and these openings may define positions of the processing channels. The opening may have various suitable shapes, such as round, rectangular, square, polygon, etc. and has a suitable size, such as a diameter or side length of about 20 nm to 500 nm. Here, these openings (especially in the device region) may be arranged in an array form, such as a two-dimensional array along horizontal and vertical directions in paper in FIG. 2(a). The array may then define an array of memory cells. Although the openings are shown to be formed on the substrate (including the device region where the memory cell will be fabricated subsequently and the contact region where a contact portion will be fabricated subsequently) with a basically consistent size and a substantially uniform density in FIG. 2(a), the present disclosure is not limited thereto. The size and/or density of the openings may be changed. For example, a density of the openings in the contact region may be less than a density of the openings in the device region, so as to reduce the resistance in the contact region.

As shown in FIG. 3, the patterned photoresist 1017 may be used as an etching mask to etch each layer on the substrate 1001 by anisotropic etching, such as reactive ion etching (RIE), so as to form a processing channel T. RIE may be performed in a substantially vertical direction (for example, a direction perpendicular to the substrate surface) and may be performed into the substrate 1001. Accordingly, a plurality of vertical processing channels T are left on the substrate 1001. A processing channel Tin the device region also defines the gate region. Then, the photoresist 1017 may be removed.

Currently, the sidewall of the sacrificial layer is exposed in the processing channel T. Accordingly, the sacrificial layer may be replaced by the isolation layer via the exposed sidewall. Considering a function of supporting the device layers 1005₁ to 1005₄ during replacement, a support layer may be formed.

For example, as shown in FIG. 4, a support material layer may be formed on the substrate 1001 by, for example, deposition, such as chemical vapor deposition (CVD). The support material layer may be formed in a substantially conformal manner. Considering the etching selectivity, especially the etching selectivity with respect to the hard mask layer 1015 (nitride in this example) and the subsequently formed isolation layer (oxide in this example), the support material layer may include, for example, SiC. By forming a photoresist 1021 and performing selective etching such as RIE with the photoresist 1021 for example, a part of the support material layer in one or more of processing channels T may be removed while a part of the support material layer in the rest of processing channels T may be retained. The remaining part of the support material layer forms a support layer 1019. In this way, on the one hand, the sacrificial layer may be replaced via a processing channel in which the support layer 1019 is not formed, and on the other hand, the device layers 1005₁ to 1005₄ may be supported by the support layer 1019 in the rest of processing channels. After that, the photoresist 1021 may be removed.

An arrangement of the processing channel in which the support layer 1019 is formed and the processing channel in which the support layer 1019 is not formed may be achieved by a pattern of the photoresist 1021. In addition, the processing channel in which the support layer 1019 is formed and the processing channel in which the support layer 1019 is not formed may be substantially evenly distributed for process consistency and uniformity. As shown in FIG. 4, the processing channel in which the support layer 1019 is formed and the processing channel in which the support layer 1019 is not formed may be arranged alternately.

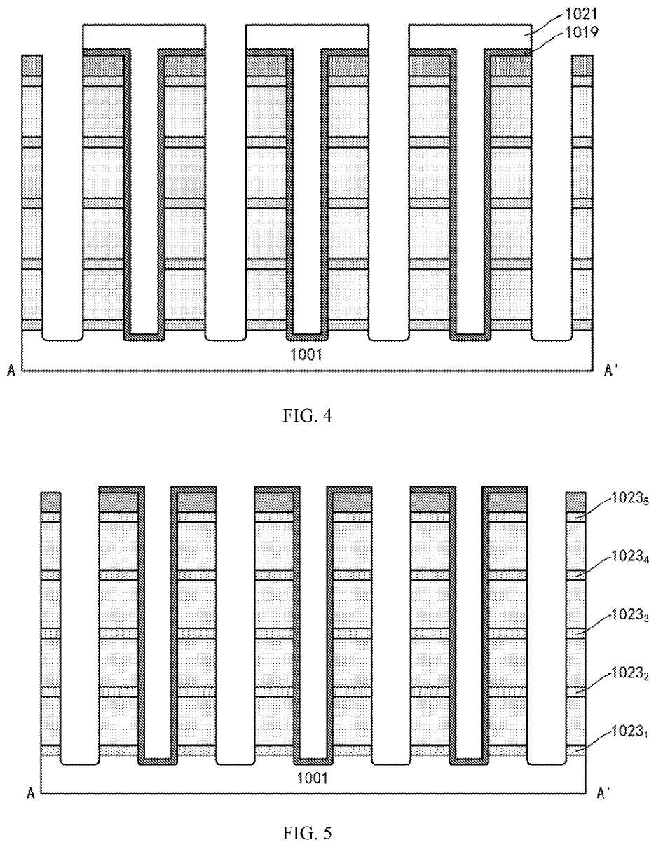

Next, as shown in FIG. 5, the sacrificial layers 1003₁ to 1003₅ may be removed by selective etching via the processing channel T. Due to the existence of the support layer 1019, the device layers 1005₁ to 1005₄ may be kept from collapsing. Gaps left by the removal of the sacrificial layers may be filled with a dielectric material to form isolation layers 1023₁, 1023₂, 1023₃, 1023₄, and 1023₅ by a process of e.g. deposition such as atomic layer deposition (ALD) or chemical vapor deposition (CVD) (preferably ALD to better control a film thickness) and then etching back (for example, RIE in the vertical direction).

According to an embodiment of the present, in order to adjust doping levels in the source/drain region and the channel region independently, the isolation layers 1023₁ to 1023₅ may contain a dopant for the source/drain region, such as an n-type dopant for an n-type memory cell, and a p-type dopant for a p-type memory cell (the doping level in the channel region may be adjusted by the doping concentration in the device layers 1005₁ to 1005₄ as described above). Accordingly, the isolation layers 1023₁ to 1023₅ may become solid phase dopant source layers. For example, the isolation layers 1023₁ to 1023₅ may include a phosphosilicate glass (PSG) (for the n-type memory cell) with a phosphorus (P) content of about 0.1% to 10%, or a borosilicate glass (BSG) (for the p-type memory cell) with a boron (B) content of about 0.1% to 10%.

In this example, the source/drain doping is achieved by the solid phase dopant source layer, which may achieve steep high source/drain doping and inhibit cross contamination caused by in situ growth during epitaxial growth.

Next, the support layer 1019 may be removed by selective etching.

The gate stack may be formed in the processing channel, especially in the processing channel of the device region. Here, a memory function may be achieved by the gate stack for forming the memory device. For example, the gate stack may include the memory functional layer. The memory functional layer may be based on charge trapping or floating gate.

According to an embodiment of the present, in order to reduce the interference between memory cells adjacent in the vertical direction, (at least) one layer (for example, a charge trapping layer or, in particular, a conductive floating gate layer) in the memory functional layer may be separated apart between adjacent memory cells instead of being continuous. For example, the (at least) one layer in the memory functional layer may be separated into portions disposed between the isolation layer above the corresponding memory cell and the isolation layer below the corresponding memory cell respectively. Therefore, a space for the (at least) one layer of the memory functional layer may be formed between isolation layers adjacent in the vertical direction. As described below, such space may be formed between isolation layers in a self-alignment manner with the corresponding device layer.

For example, as shown in FIG. 6, each of the device layers 1005₁ to 1005₄ may be recessed to a certain extent in the transverse direction by selective etching. The etching may be isotropic, so that each of the device layers 1005₁ to 1005₄ may be recessed to substantially the same depth in the transverse direction, so as to result in an annular gap centered on the processing channel T between each pair of isolation layers adjacent in the vertical direction. The sidewalls of respective device layer may still be substantially coplanar in the vertical direction after etching. In this example, the device layer includes silicon, and therefore, when the device layer is etched, the substrate 1001, which is also silicon, may also be etched.

The memory functional layers may be respectively formed in processing channels with such annular gaps.

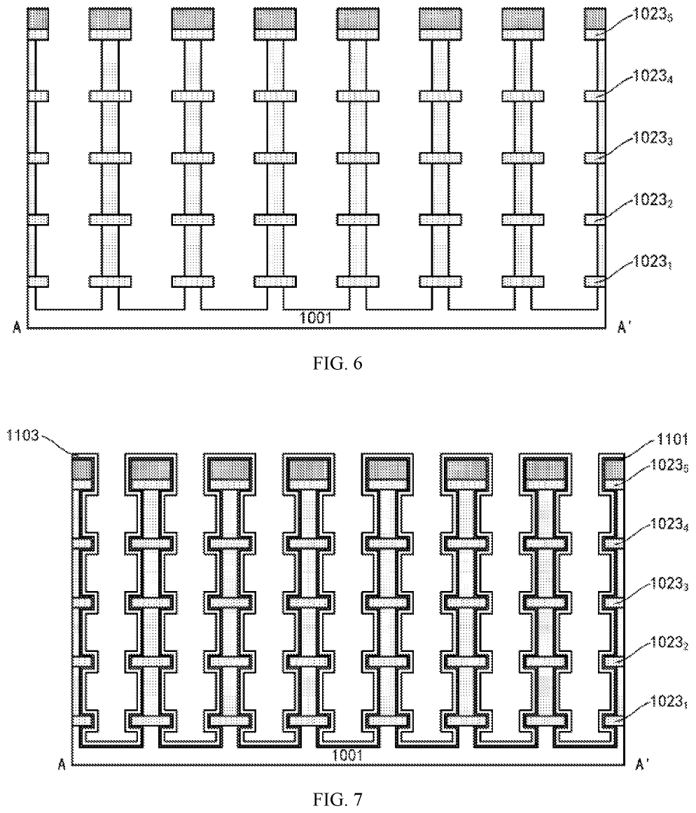

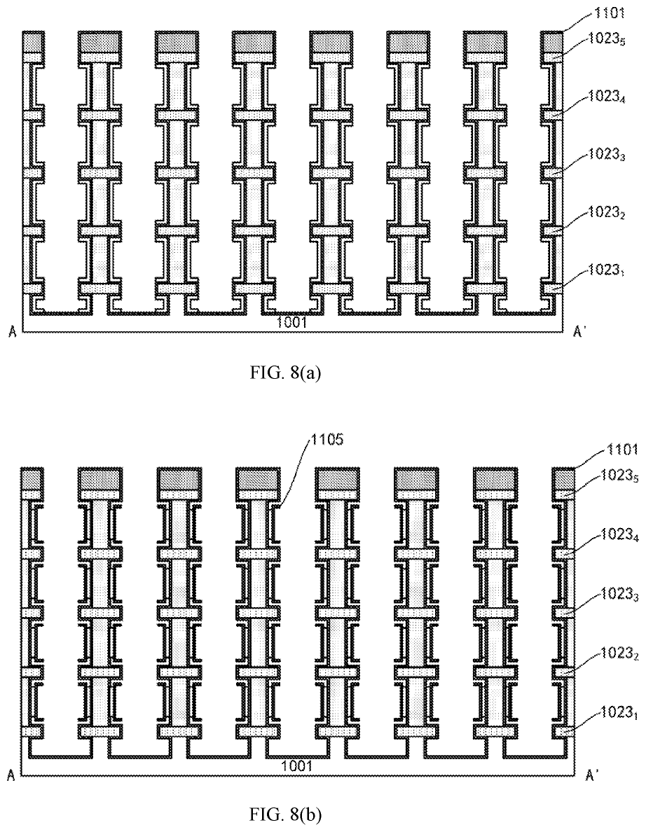

For example, as shown in FIG. 7, a first gate dielectric layer 1101 and a preparatory layer 1103 may be sequentially formed by deposition, such as ALD or CVD (preferably ALD, to better control a film thickness). The first gate dielectric layer 1101 and the preparatory layer 1103 may be formed in a substantially conformal manner. For example, the first gate dielectric layer 1101 may include oxide (which may also be formed by an oxidation process rather than deposition), and may have a thickness of about 1 nm to 5 nm. The preparatory layer 1103 may be used to store charges, e.g. may be a floating gate layer (of a conductive material, such as doped polysilicon or metal) with a thickness of about 1 nm to 10 nm, or a charge trapping layer (of e.g. nitride) with a thickness of about 2 nm to 10 nm. The thickness of the first gate dielectric layer 1101 and the thickness of the preparatory layer 1103 may be controlled, so that a transverse recess shape with respect to the hard mask layer 1015 may be maintained.

As shown in FIG. 8(a), portions (for example, portions on sidewalls of respective isolation layers and the hard mask layer) of the preparatory layer 1103 that are relatively prominent in the transverse direction may be removed by, for example, RIE in the vertical direction. Accordingly, the preparatory layer 1103 is separated into sections left between each pair of isolation layers adjacent in the vertical direction, and such sections may be self-aligned with corresponding device layers respectively.

According to another embodiment of the present, after the preparatory layer 1103 is formed as described above in combination with FIG. 7, a protective layer 1105 is formed on the preparatory layer 1103, for example, by deposition (see FIG. 8(b)). The protective layer 1105 may also be formed in a substantially conformal manner, and may maintain a transverse recess shape with respect to the hard mask layer 1015. For example, the protective layer 1105 may include nitride or carbide with a thickness of about 1 nm to 3 nm. Then, as shown in FIG. 8(b), portions of each of the protective layer 1105 and the preparatory layer 1103 that is relatively prominent in the transverse direction may be removed successively by, for example, RIE in the vertical direction, as described above in combination with FIG. 8(a). Then, in a case that the protective layer 1105 is present, the separated sections of the preparatory layer 1103 may be over etched, in order to be further recessed, ensuring that they are fully separated from each other. For example, a portion of each of the separated sections of the preparatory layer 1103 that extends in the transverse direction may be removed, leaving a portion extending in the vertical direction on a sidewall of the corresponding device layer. Such over etching may be isotropic etching, so that each left section may have basically the same size, and may keep self-alignment with the corresponding device layer. The protective layer 1105 may then be removed by selective etching.

In the following, the case shown in FIG. 8(a) is described as an example, and these descriptions are also applicable to the case shown in FIG. 8(b).

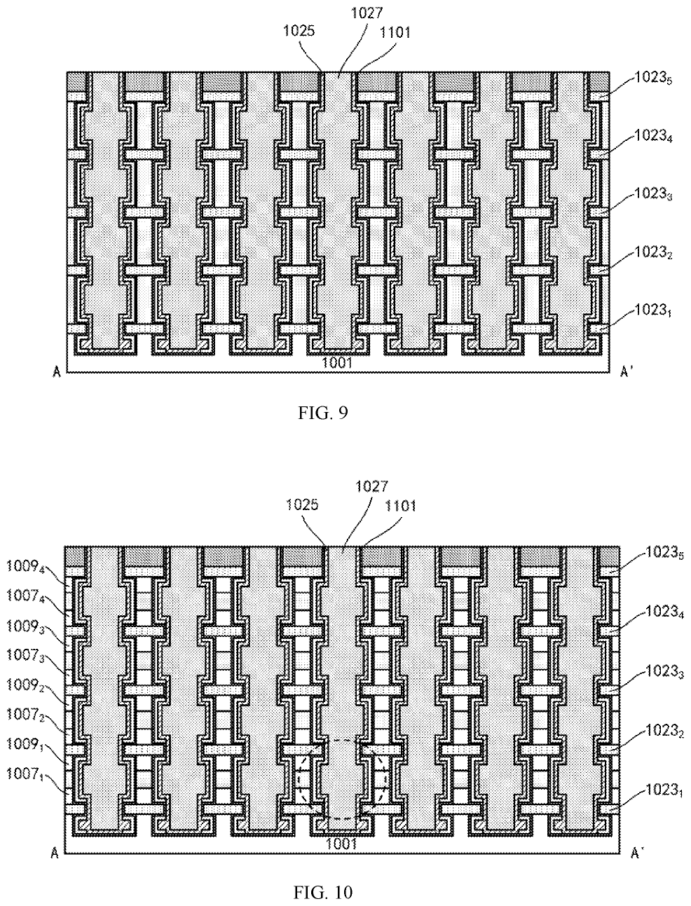

Next, as shown in FIG. 9, a second gate dielectric layer 1025 and a gate conductor layer 1027 may be formed sequentially by, for example, deposition. The second gate dielectric layer 1025 may be formed in a substantially conformal manner. A gap left in the processing channel T may be filled with the gate conductor layer 1027. For example, the second gate dielectric layer 1025 may include oxide (which may also be formed by an oxidation process rather than deposition), and a thickness of the second gate dielectric layer 1025 is about 2 nm to 10 nm. The gate conductor layer 1027 may include a conductive material, for example, (doped, such as p-doped in the case of the n-type device) polysilicon or a metal gate material. A planarization treatment, such as chemical mechanical polishing (CMP, for example, CMP may stop at the hard mask layer 1015), may be performed on the formed gate conductor layer 1027, the formed second gate dielectric layer 1025, and the formed first gate dielectric layer 1101, so that the gate conductor layer 1027, the second gate dielectric layer 1025, and the first gate dielectric layer 1101 may be left in the processing channel T to form the gate stack along with respective sections of the preparatory layer 1103.

Here, each section of the preparatory layer 1103 is between the first gate dielectric layer 1101 and the second gate dielectric layer 1025. For example, when the preparatory layer 1103 is a floating gate layer of conductive material, the sections of the preparatory layer 1103 may form a floating gate configuration with the first gate dielectric layer 1101, so as to be used as as the memory functional layer. Alternatively, when the preparatory layer 1103 is a charge trapping layer, such as a nitride, a three-layer structure of the first gate dielectric layer 1101 (for example, oxide)—the section of the preparatory layer 1103 (for example, nitride)—the second gate dielectric layer 1023 (for example, oxide) may lead to an energy band structure that traps electrons or holes, so as to be used as the memory functional layer. Of course, there may be other memory functional layers, such as a ferroelectric material layer. In this example, a double gate dielectric configuration of the first gate dielectric layer 1101 and the second gate dielectric layer 1025 is used to achieve a floating gate configuration or a bandgap engineering charge memory configuration. However, the present disclosure is not limited thereto. Different gate dielectric configurations (for example, a single layer, or three or more layers) may be used depending on a memory functional layer used.

As shown in FIG. 10, annealing treatment may be performed to drive the dopant in the solid phase dopant source layer into the device layer. For each of the device layers 1005₁ to 1005₄, a dopant in the isolation layers at an upper end of the device layer and a dopant in the isolation layers at a lower end of the device layer enter the device layer from the upper and lower ends respectively, so that highly doped regions 1007₁ and 1009₁, 1007₂ and 1009₂, 1007₃ and 1009₃, and 1007₄ and 1009₄ (for example, n-type doping of about 1E19 cm⁻³ to 1E21 cm⁻³), may be formed at the upper and lower ends of each of the device layers 1005₁ to 1005₄, so as to define the source/drain regions. Here, a diffusion depth of the dopant from the isolation layer to the device layer may be controlled (for example, to be about 10 nm to 50 nm), so that a middle portion of each device layer in the vertical direction may keep to have relatively low doping, e.g. to have substantially the doping polarity (for example, p-type doping) and doping concentration (for example, 1E17 cm⁻³ to 1E19 cm⁻³) caused by the in situ doping during growth, and may define the channel region.

The doping concentration achieved by in situ doping is generally lower than 1E20 cm-3. According to an embodiment of the present disclosure, the source/drain doping is performed by diffusion from the solid phase dopant source layer, which may achieve high doping, for example, the highest doping concentration may be higher than 1E20 cm-3, or even up to about 7E20 cm⁻³ to 3E21 cm⁻³. In addition, due to the diffusion characteristics, the source/drain region may have a doping concentration gradient that decreases, in the vertical direction, from a side of the source/drain region close to the solid dopant source layer to a side of the source/drain region close to the channel region.

Such diffusion doping may achieve a steep doping concentration distribution. For example, there may be a steep sharp change in doping concentration between the source/drain region and the channel region, e.g. less than about 5 nm/dec to 20 nm/dec (that is, a decrease of the doping concentration by at least one order of magnitude occurs in a range of less than about 5 nm to 20 nm). The region having such sharp change in the vertical direction may be called an “interface layer”.

Since the diffusion from each isolation layer diffuses into the device layer has substantially the same diffusion characteristics, each of the source/drain regions 1007₁, 1009₁, 1007₂, 1009₂, 1007₃, 1009₃, 1007₄, and 1009₄ may be substantially coplanar in the transverse direction. Similarly, each channel region may be substantially coplanar in the transverse direction. In addition, as described above, the channel region may have a non-uniform distribution in the vertical direction. The doping concentration in a region of the channel region close to the source/drain region (the drain region) on one side of the channel region is relatively high, while the doping concentration in a region of the channel region close to the source/drain region (the source region) on the other side of the channel region is relatively low.

In the above embodiment, the gate stack is formed, and then the source/drain diffusion doping is performed. However, the present disclosure is not limited thereto, and order of these steps may be changed. For example, the source/drain diffusion doping may be performed before forming the gate stack, or even in the process of forming the gate stack (the process of forming the gate stack may include forming a plurality of layers, such as the first gate dielectric layer, the preparatory layer, the second gate dielectric layer, and the gate conductor layer described above).

As shown in FIG. 10, the gate stack (1101/1103/1025/1027) having the memory functional layer is surrounded by the device layer. The gate stack is cooperated with the device layer to define the memory cell, as shown in a dotted circle in FIG. 10. The channel region may be connected to source/drain regions at opposite sides of the channel region, and the channel region may be controlled by the gate stack. One of source/drain regions at upper and lower ends of a single memory cell is used as the source region and may be electrically connected to the source line. The other one of the source/drain regions at the upper and lower ends of the single memory cell is used as the drain region and may be electrically connected to the bit line. For every two adjacent memory cells in the vertical direction, a source/drain region at an upper end of the lower one of the two memory cells and a source/drain region at a lower end of the upper one of the two memory cells may be used as source regions, and thus may share the same source line connection.

The gate stack extends in a column shape in the vertical direction and intersects with a plurality of device layers, so as to define a plurality of memory cells stacked on each other in the vertical direction. Memory cells associated with a single gate stack column may form a memory cell string. Corresponding to an arrangement of the gate stack columns (corresponding to the above-mentioned arrangement of the processing channels T, such as the two-dimensional array), a plurality of such memory cell strings are arranged on the substrate, so as to form a three-dimensional (3D) array of memory cells.

In this way, the fabrication of the memory cell (in the device region) is completed. Then, various electrical contact portions may be fabricated (in the contact region) to achieve a desired electrical connection.

In order to achieve an electrical connection to each device layer, a step structure may be formed in the contact region. Such step structure may be formed in various manners in the art. According to an embodiment of the present disclosure, the step structure may be formed as follows, for example.

As shown in FIG. 10, the current gate stack is exposed at a surface of the hard mask layer 1015. In order to protect the gate stack (in the device region) when fabricating the step structure as following, another hard mask layer 1029 may be formed on the hard mask layer 1015, as shown in FIGS. 11(a), 11(b), and 11(c). For example, the hard mask layer 1029 may include oxide. A photoresist 1031 may be formed on the hard mask layer 1029. The photoresist 1031 is patterned by photolithography to shield the device region and expose the contact region. Selective etching such as RIE may be performed on the hard mask layer 1029, the hard mask layer 1015, the isolation layer 1023₅, and the gate stack by using the photoresist 1031 as an etching mask, so as to expose the device layer. A surface exposed by the photoresist 1031 in the contact region after etching may be substantially planar by controlling an etching depth. For example, the hard mask layer 1029 may be etched and then the gate conductor layer 1027 is etched. The etching of the gate conductor layer 1027 may be stopped near a top surface of the device layer 1005₄. Then the hard mask layer 1015 and the isolation layer 1023₅ may be etched sequentially. After such etching, a top end of the first gate dielectric layer 1101 and a top end of the second gate dielectric layer 1025 may be protruded above the top surface of the device layer 1005₄ and may be removed by RIE. In this way, a step is formed between the contact region and the device region. Then, the photoresist 1031 may be removed.

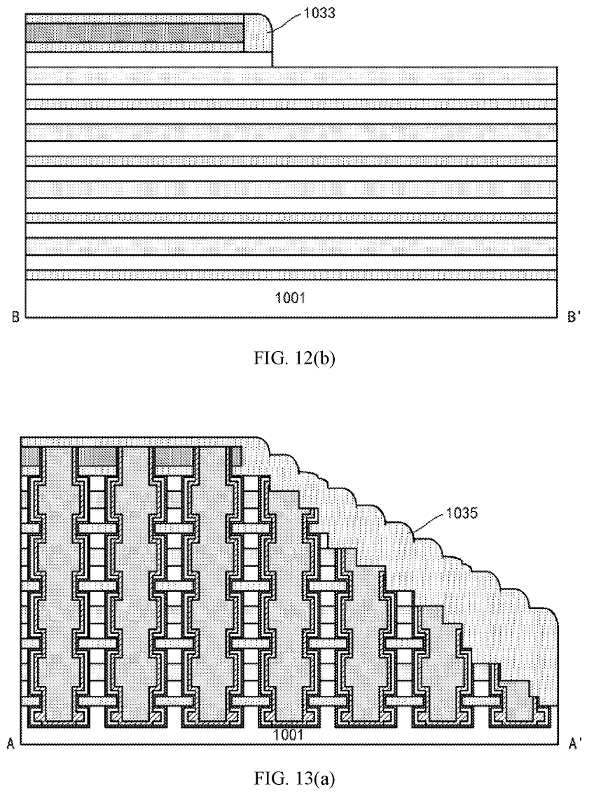

As shown in FIGS. 12(a) and 12(b), a spacer 1033 may be formed at the step between the contact region and the device region through a spacer formation process. For example, a layer of dielectric such as oxide may be deposited in a substantially conformal manner, and then anisotropic etching such as RIE in the vertical direction may be performed on the deposited dielectric, so as to remove a transverse extending portion of the deposited dielectric and retain a vertical extending portion of the deposited dielectric, thereby forming the spacer 1033. Here, considering that the hard mask layer 1029 also includes oxide, an etching depth of the RIE may be controlled to be substantially equal to or slightly greater than a deposition thickness of the dielectric, so as to avoid completely removing the hard mask layer 1029. A width of the spacer 1033 (in the horizontal direction in FIGS. 12(a) and 12(b)) may be basically equal to the deposition thickness of the dielectric. The width of the spacer 1033 defines a size of a landing pad of a contact portion to the source/drain region 1009₄ in the device layer 1005₄.

Selective etching such as RIE may be performed on the exposed source/drain region 1009₄ in the device layer 1005₄ and the gate stack by using the formed spacer 1033 as an etching mask, so as to expose the channel region in the device layer 1005₄. A surface exposed by the spacer 1033 in the contact region after etching may be substantially planar by controlling an etching depth. For example, the source/drain region 1009₄ and the gate conductor layer 1027 may be etched. For example, the source/drain region 1009₄ and the gate conductor layer 1027 are Si and polycrystalline Si respectively; and if the gate conductor layer 1027 includes a metal gate, the source/drain region 1009₄ and the gate conductor layer 1027 may be etched separately. The etching of the source/drain region 1009₄ and the gate conductor layer 1027 may be stopped at the channel region in the device layer 1005₄. After such etching, the top end of the first gate dielectric layer 1101 and the top end of the second gate dielectric layer 1025 (and optionally, a top end of a section of the preparatory layer 1103) may be protruded above the channel region in the device layer 1005₄ and may be removed by RIE. In this way, another step is formed between the source/drain region 1009₄ in the device layer 1005₄ and the surface exposed by the spacer 1033 in the contact region.

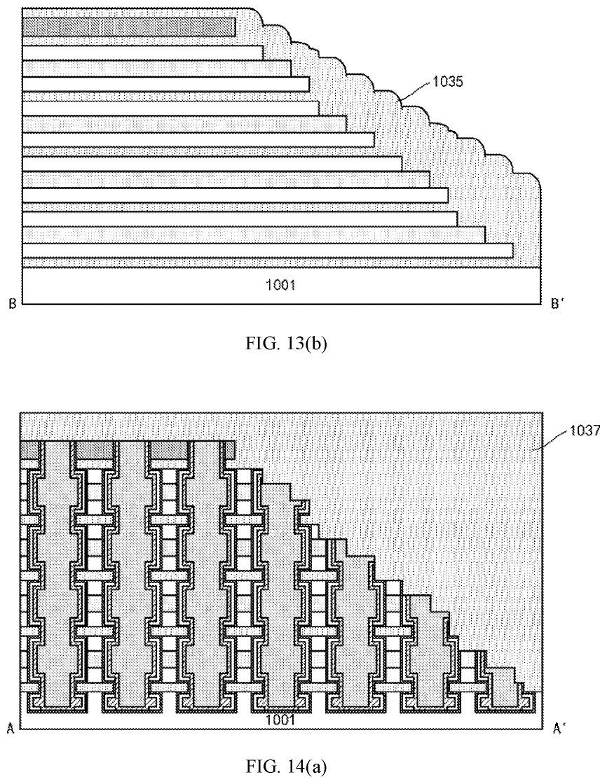

According to the process described above in combination with FIGS. 12(a) and 12(b), the spacer is formed and etching is performed by taking the spacer as the etching mask. Accordingly, a plurality of steps may be formed in the contact region, as shown in FIGS. 13(a) and 13(b). Such steps form such a step structure that in each device layer, each of the source/drain regions to be electrically connected and optionally the channel region, has an end portion protruded with respect to the upper region, so as to define a landing pad of a contact portion to the region. A portion of each formed spacer being left after processing is denoted by 1035 in FIGS. 13(a) and 13(b). Since both the spacer 1035 and the isolation layer are oxide, they are shown here as integral.

Next, the contact portion may be fabricated.

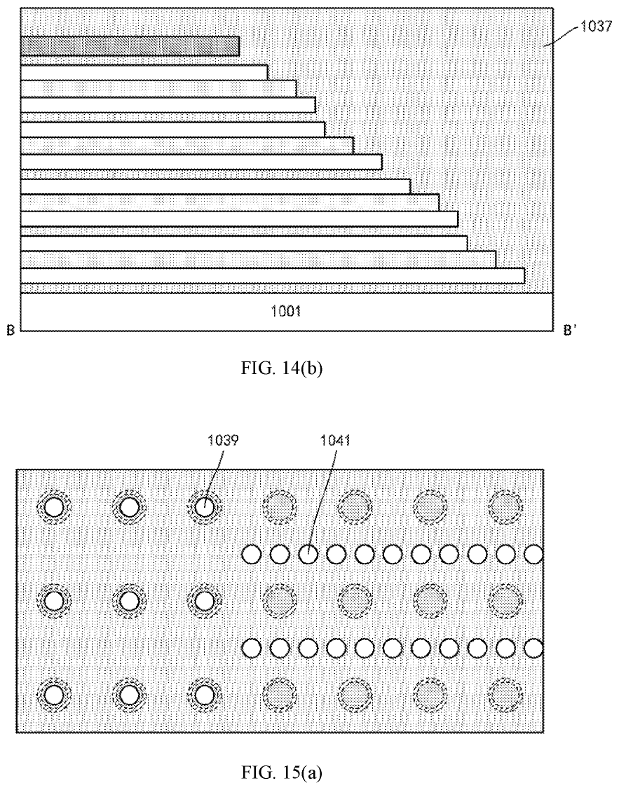

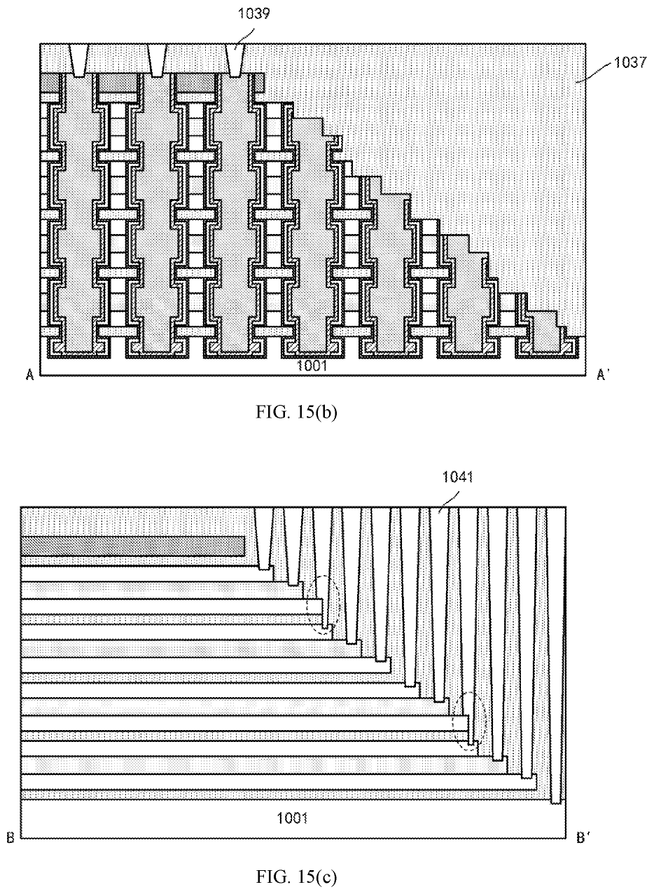

For example, as shown in FIGS. 14(a) and 14(b), an interlayer dielectric layer 1037 may be formed by depositing oxide and planarization such as CMP. Here, since the previously formed spacer 1035 and isolation layer, and the interlayer dielectric layer 1037 are oxides, they are shown as integral. Then, as shown in FIGS. 15(a), 15(b), and 15(c), contact portions 1039 and 1041 may be formed in the interlayer dielectric layer 1037. Specifically, the contact portion 1039 is formed in the device region and electrically connected to the gate conductor layer 1027 in the gate stack. The contact portion 1041 is formed in the contact region and electrically connected to each source/drain region and optionally the channel region. The contact portion 1041 in the contact region may bypass the gate stack left in the contact region. Such contact portions may be formed by etching the interlayer dielectric layer 1037 to obtain holes and filling the holes with a conductive material such as a metal.

Here, the contact portion 1039 may be electrically connected to a word line. A gate control signal may be applied to the gate conductor layer 1027 through the word line via the contact portion 1039. For every two adjacent memory cells in the vertical direction, source/drain regions located in the middle, i.e. the source/drain region 1009₁ in the first device layer 1005₁ and the source/drain region 1007₂ in the second device layer 1005₂, or the source/drain region 1009₃ in the third device layer 1005₃ and the source/drain region 1007₄ in the fourth device layer 1005₄, may be electrically connected to a source line via the common contact portion 1041, as shown in dotted circles in FIG. 15(c). The source/drain regions located at upper and lower ends, i.e. the source/drain region 1007₁ in the first device layer 1005₁ and the source/drain region 1009₂ in the second device layer 1005₂, or the source/drain region 1007₃ in the third device layer 1005₃ and the source/drain region 1009₄ in the fourth device layer 1005₄, may be electrically connected to the bit lines via the contact portion 1041 respectively. In this way, a NOR-type configuration may be obtained. Here, a contact portion to the channel layer is also formed. Such contact portion may be called a bulk contact portion and may receive a bulk bias, so as to adjust a threshold voltage of the device.

Here, the two adjacent memory cells in the vertical direction are configured such that the source/drain regions located near the interface between the two adjacent memory cells are electrically connected to the source line. This may reduce the amount of cabling. However, the present disclosure is not limited thereto. For example, adjacent memory cells in the vertical direction may have the same configuration, i.e. a configuration of source region—channel region—drain region or a configuration of drain region—channel region—source region.

In this embodiment, the isolation layer (used as the solid phase dopant source layer) containing the dopant is reserved. However, the present disclosure is not limited thereto. After diffusion doping, another material may be used to replace the solid phase dopant source layer. For example, the solid phase dopant source layer may be replaced by another dielectric material, especially a dielectric material that does not intentionally contain a dopant, so as to improve the isolation performance. Alternatively, every two device layers adjacent in the vertical direction are taken as a group, and the solid phase dopant source layer between the device layers of each group (for example, the solid phase dopant source layer 1023₂ between device layers 1005₁ and 1005₂ as a group, and the solid phase dopant source layer 1023₄ between device layers 1005₃ and 1005₄ as a group) may be replaced by a conductive material such as a metal or a doped semiconductor layer, so as to reduce an interconnection resistance (to the source line). Solid phase dopant source layers on upper and lower sides of each group (for example, the solid phase dopant source layer 1023₁ on a lower side of the group of device layers 1005₁ and 1005₂, the solid phase dopant source layer 1023₃ on an upper side of the group of device layers 1005₁ and 1005₂ as well as on a lower side of the group of device layers 1005₃ and 1005₄, and the solid phase dopant source layer 1023₅ on an upper side of the group of device layers 1005₃ and 1005₄) may be replaced by a dielectric material, so as to achieve an isolation between bit lines. When the solid phase dopant source layer is replaced, the “interface layer” having the sharp change in doping concentration as described above may also be formed at a side of the source/drain region away from the channel region.

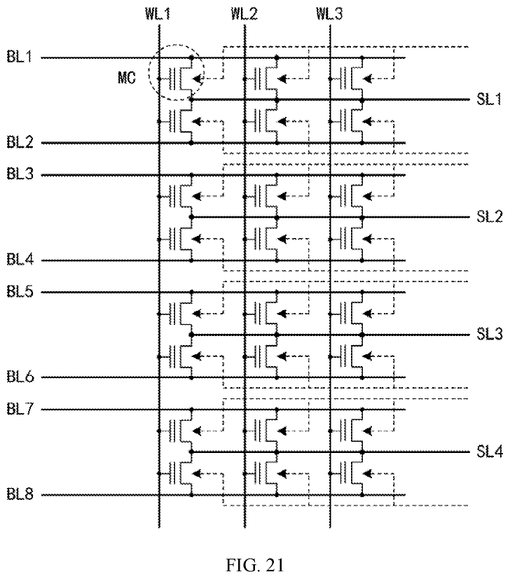

FIG. 21 schematically shows an equivalent circuit diagram of a NOR-type memory device according to an embodiment of the present disclosure.

In an example of FIG. 21, three word lines WL1, WL2, and WL3 and eight bit lines BL1, BL2, BL3, BL4, BL5, BL6, BL7, and BL8 are schematically shown. However, specific numbers of bit lines and word lines are not limited thereto. A memory cell MC is provided at an intersection of the bit line and the word line. FIG. 21 also shows four source lines SL1, SL2, SL3, and SL4. As described above, every two adjacent device layers may share the same source line connection. In addition, respective source lines may be connected to each other, so that respective memory cells MC may be connected to a common source line. In addition, an optional bulk connection to each memory cell is schematically shown in FIG. 21 with dotted lines. As described below, the bulk connection of each memory cell may be electrically connected to a source line connection of the memory cell.

Here, a two-dimensional array of memory cells MC is shown for illustration convenience only. A plurality of such two-dimensional arrays may be arranged in a direction (for example, a direction perpendicular to the paper surface in FIG. 21) of intersection with this two-dimensional array, so as to obtain a three-dimensional array.

In FIG. 21, an extension direction of the word lines WL1 to WL3 may correspond to an extension direction of the gate stack, that is, the vertical direction with respect to the substrate in the above embodiment. In this direction, adjacent bit lines are isolated from each other.

In the above embodiment, the contact portion 1041 in the contact region is desired to bypass the gate stack left in the contact region. According to another embodiment of the present disclosure, an isolation such as the dielectric material may be formed at a top end of the gate stack left in the contact region, so that it is not necessary to deliberately bypass the residual gate stack.

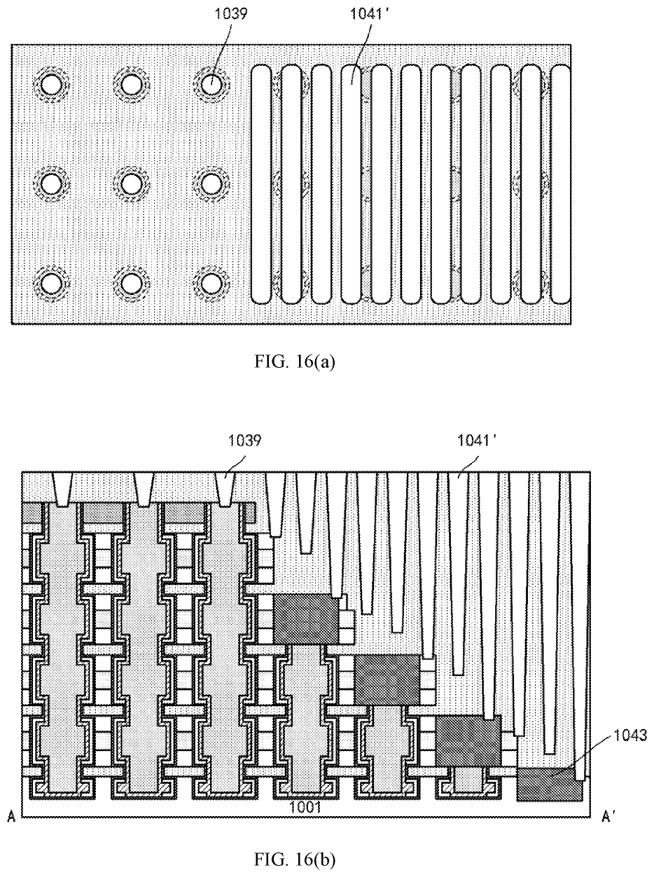

For example, as shown in FIGS. 16(a) and 16(b), after the step structure is formed in the contact region as described above in combination with FIGS. 11(a) to 13(b), the isolation layer and the spacer 1035 may be removed by selective etching, such as RIE, so as to expose a top end of each gate stack (in the device region and the contact region). The gate stack in the device region may be shielded by a shielding layer, such as a photoresist, so as to expose the gate stack in the contact region. For the gate stack exposed in the contact region, the gate conductor layer may be recessed by a factor of, for example, about 50 nm to 150 nm, through selective etching such as RIE. Each material layer exposed due to the recess of the gate conductor layer, especially the conductive material layer (for example, the floating gate layer), may be etched. After that, the shielding layer may be removed. A gap formed due to the etching of the gate conductor layer and other material layers in the contact region may be filled with the dielectric material such as SiC by, for example, deposition followed by etching back, so as to form an isolation plug 1043.

Next, the interlayer dielectric layer may be formed according to the above embodiment, and contact portions 1039 and 1041′ may be formed in the interlayer dielectric layer. In this example, the contact portion 1041′ in the contact region may extend into the isolation plug 1043. Therefore, the contact portion 1041′ may not be limited to be in form of plug described above, but may be formed as a strip, so as to reduce a contact resistance. The strip contact portion 1041′ may extend along a landing pad (i.e., the step in the step structure) of a corresponding layer.

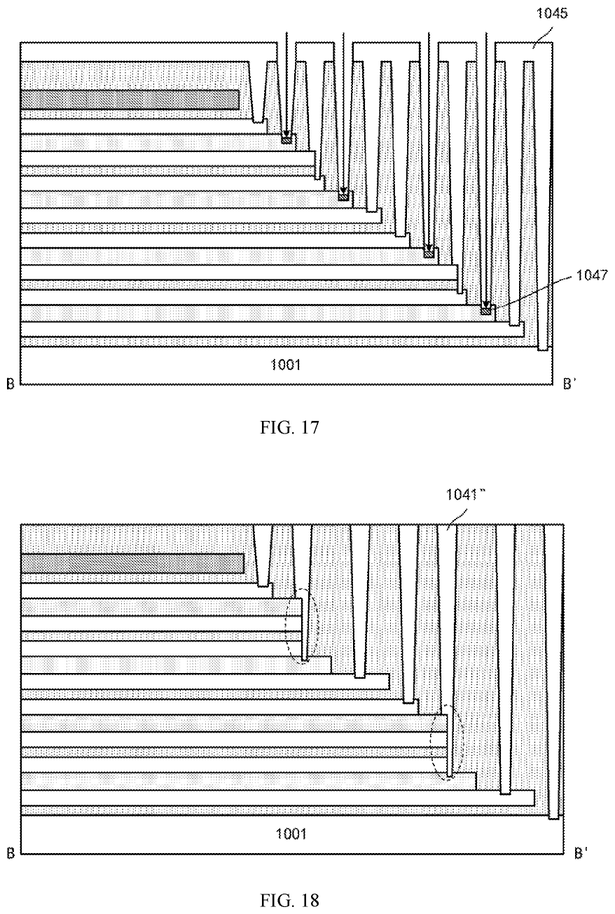

In the above embodiment, since the channel layer is lightly doped or not intentionally doped, a contact resistance between the bulk contact portion and the channel layer may be relatively large. According to another embodiment of the present disclosure, a highly doping (with respect to at least a part of the channel layer) may be formed at a position where the channel layer is in contact with the bulk contact portion, so as to reduce the contact resistance. For example, as shown in FIG. 17, after the interlayer dielectric layer is formed and the holes for the contact portions are formed in the interlayer dielectric layer by etching as described above, a photoresist 1045 may be formed. The photoresist 1045 is patterned by photolithography to expose holes for bulk contact portions to be formed. A highly doped region 1047 may be formed in a landing pad of the channel layer via these holes by, for example, ion implantation. A doping type of the highly doped region 1047 may be the same as a doping type of the channel layer, but a doping concentration of the highly doped region 1047 is relatively high. Then, the photoresist 1045 may be removed. After that, the contact portions may be formed in the holes of the interlayer dielectric layer.

In the above embodiment, the bulk contact portion is provided separately. According to another embodiment of the present disclosure, the bulk contact portion may be integrated with a source line contact portion, so as to save area. For example, as shown in FIG. 18, a contact portion 1041″ may be in contact with each channel region of two adjacent device layers and source/drain regions between the channel regions. Instead of forming a step between every adjacent region in the above embodiment, in the embodiment of FIG. 18, a step may be formed only between the upper three regions and the lower one region of four regions including the channel region of the two adjacent device layers and the source/drain regions between the channel regions, so as to save area.

In the above embodiment, the contact portion is in direct contact with the corresponding landing pad. According to another embodiment of the present disclosure, silicide may be formed at the landing pad, so as to reduce the contact resistance. More specifically, at each step of the contact region, a transverse surface of the step is used as a landing pad on which silicide may be formed. On the other hand, silicide may not be formed on a vertical surface of the step, so as to avoid a short circuit between landing pads of adjacent steps.

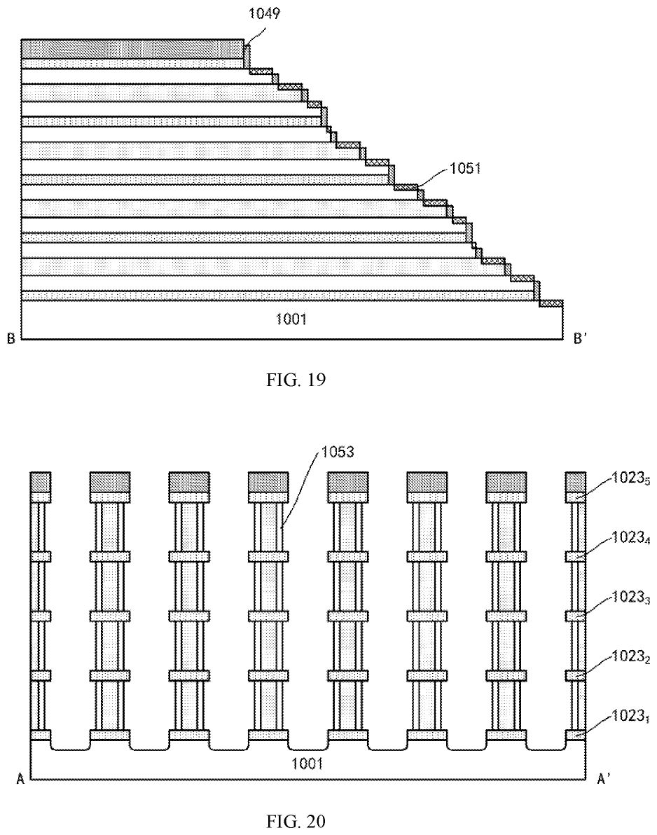

For example, as shown in FIG. 19, after the step structure is formed in the contact region as described above in combination with FIGS. 11(a) to 13(b), the isolation layer and the spacer 1035 may be removed by selective etching such as RIE, so as to expose a surface of each step in the contact region. A dielectric spacer 1049 may be formed on the vertical surface of each step by the spacer formation process, so as to shield the vertical surface of each step to avoid a subsequent silicification reaction. Then, an exposed transverse surface of each step may be silicified. For example, a metal such as NiPt may be deposited and annealed, so that silicification reaction is conducted between the deposited metal and a semiconductor material (such as Si) at the transverse surface of each step, so as to generate a conductive metal silicide 1051 such as NiPtSi. An unreacted metal may then be removed.

In the example as shown, the gate conductor layer 1027 is polysilicon for example. Accordingly, a top end of the gate conductor layer 1027 may also undergo the silicification reaction and thus be covered by silicide. When the gate conductor layer 1027 is the metal gate, a protective layer (for example, nitride) may be formed on the device region to cover the gate stack and then be silicified. Accordingly, the gate conductor layer 1027 may be prevented from being damaged by etching when removing the metal in the silicification process.

Next, the interlayer dielectric layer may be formed as described above, and the contact portions 1039 and 1041 may be formed in the interlayer dielectric layer. When etching the holes used for the contact portions, the silicide 1051 may be used as an etching stop layer. Therefore, an etching depth of the hole may be better controlled.

In the above embodiment, the active region is defined by the device layer as the bulk material, and therefore the channel region is formed in the bulk material. In this case, the process is relatively simple. However, the present disclosure is not limited thereto.

After forming the annular gap as described above in combination with FIG. 6, an active layer may be formed in such annular gap, and then the gate stack with the memory functional layer may be formed as described above. For example, as shown in FIG. 20, another semiconductor layer 1053 may be respectively formed on an exposed surface of each device layer 1005₁ to 1005₄, for example, by selective epitaxial growth. The semiconductor layer 1053 may be located in the above-mentioned annular gap. The semiconductor layer 1053 may include various suitable semiconductor materials such as Si. A material and/or thickness of the semiconductor layer 1053 may be selected to improve the device performance. For example, the semiconductor layer 1053 may include a material such as Ge, IV-IV compound semiconductor such as SiGe, III-V compound semiconductor, etc., which is different from the material(s) of the device layers (in this example, Si for all the device layers), to improve the carrier mobility or reduce the leakage current. Adjacent semiconductor layers 1053 in the vertical direction may be isolated from each other by the isolation layer. After that, the process may be performed as above. For example, the gate stack may be formed in the processing channel. At least one layer of the memory functional layers in each gate stack may have portions separated from each other, and each portion of the memory functional layer may be self-aligned with the corresponding semiconductor layer 1053.

According to another embodiment, the SSRW may further be formed. For example, the dopant in each of the device layers 1005₁ to 1005₄ may also diffuse transversely into adjacent semiconductor layer 1053 during the annealing treatment. As described above, in the vertical direction, the dopant(s) from the isolation layers 1023₁ to 1023₅ do not substantially affect a middle portion of the semiconductor layer 1053 due to the diffusion depth. Therefore, a doping distribution in the middle portion of the semiconductor layer 1053 is mainly determined by the transverse diffusion from each of the device layers 1005₁ to 1005₄, and the channel region may be defined. A processing condition of the annealing treatment, such as an annealing time, may be controlled so that in the middle portion of the semiconductor layer 1053, a doping concentration at a sidewall (and its vicinity) of the semiconductor layer 1053 away from the corresponding device layer in the transverse direction is lower than a doping concentration at a sidewall (and its vicinity) adjacent to the corresponding device layer. Accordingly, the SSRW may be formed, and good control of the short channel effect may be obtained.

In the above embodiment, a single gate stack is formed in each processing channel T. However, the present disclosure is not limited thereto. To further increase integration, two or more gate stacks may be formed in each processing channel T.

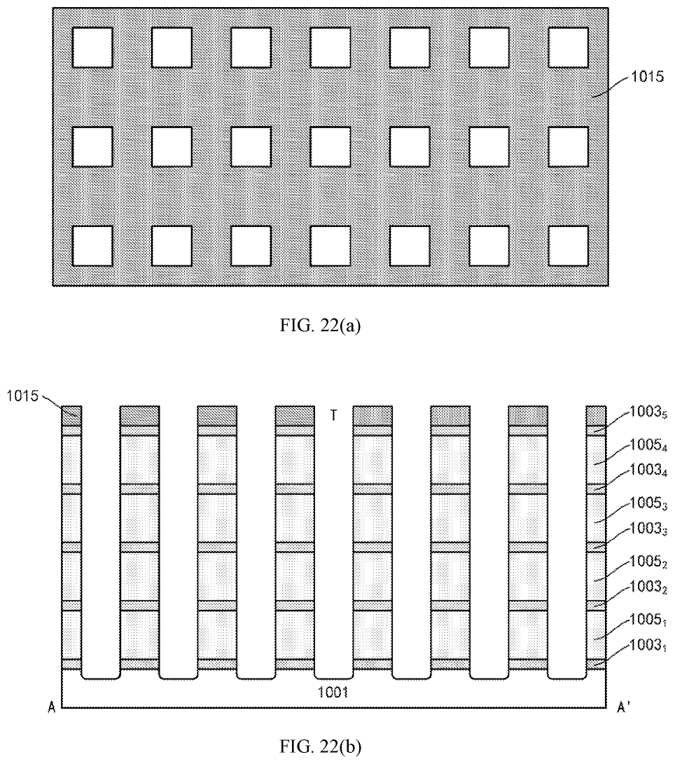

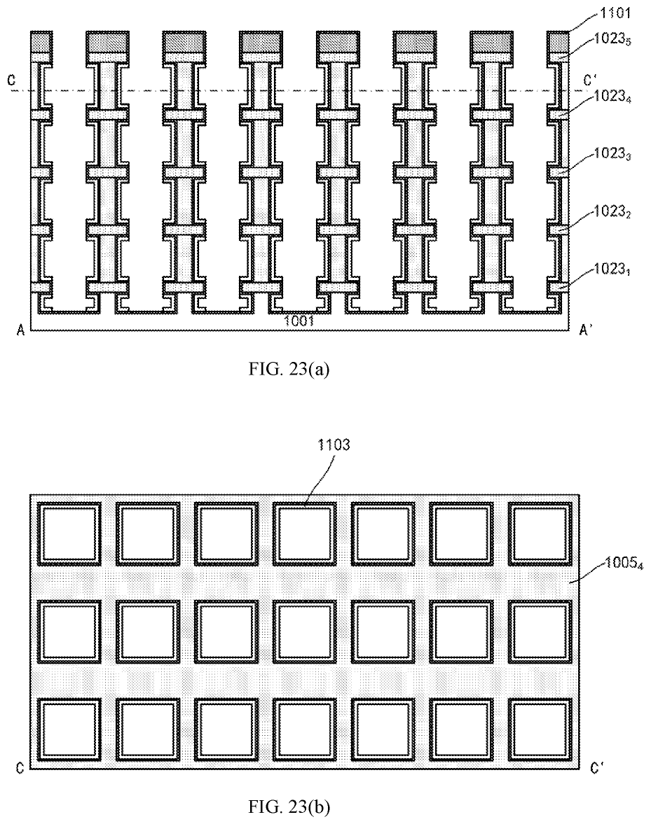

FIGS. 22(a) to 27 are schematic diagrams showing some stages in a process of manufacturing a NOR-type memory device according to another embodiment of the present disclosure.

As shown in FIGS. 22(a) and 22(b), the processing channel T may be formed as described above in combination with FIGS. 1 to 3. Here, the processing channel T may be formed to have a rectangle shape or a square shape. Such a rectangular or square configuration is beneficial to maintaining the device consistency, but the present disclosure is not limited thereto.

As shown in FIGS. 23(a) and 23(b), the sacrificial layer may be replaced by the isolation layer as described above in combination with FIGS. 4 and 5, and the first gate dielectric layer 1101 and the preparatory layer 1103 may be formed as described above in combination with FIGS. 6 to 8(b). The preparatory layer 1103 may be separated into sections corresponding to the plurality of device layers. As shown in the plane view in FIG. 23(b), at present, each section of the preparatory layer 1103 extends continuously along the sidewall of the processing channel T.

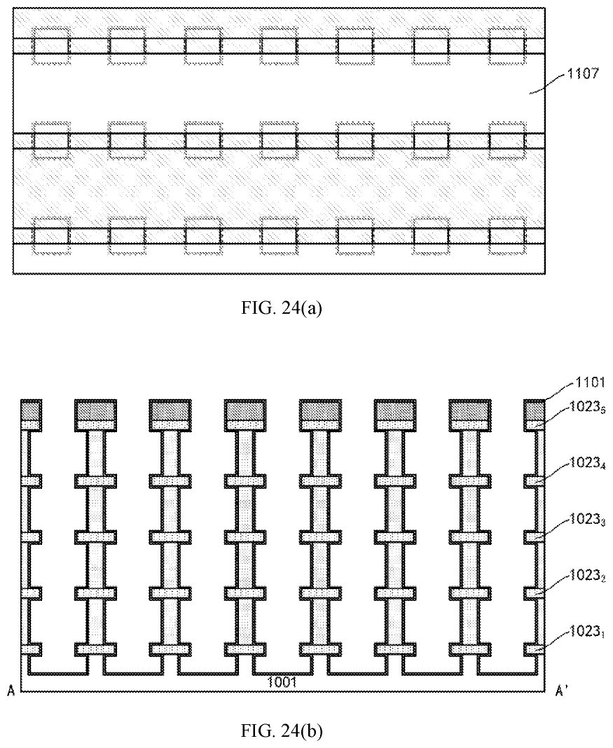

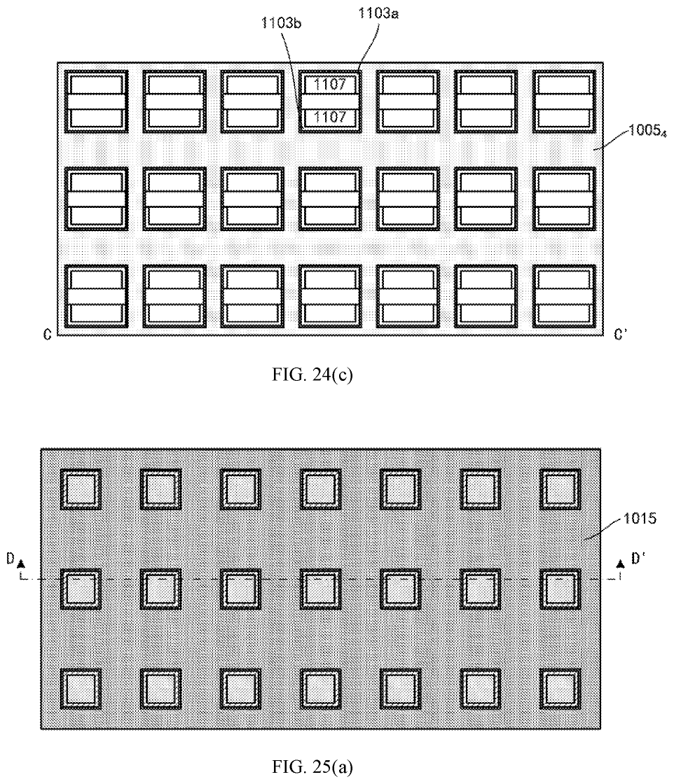

Each section of the preparatory layer 1103 may be further divided. For example, as shown in FIGS. 24(a) to 24(c), a photoresist 1107 may be formed. The photoresist 1107 may be patterned to expose a portion of each section of the preparatory layer 1103. Such patterned photoresist 1107 is used as an etching mask to selectively etch each section of the preparatory layer 1103, so as to remove the exposed portion of each section of the preparatory layer 1103. After that, the photoresist 1107 may be removed. Accordingly, each section of the preparatory layer 1103 is further divided into discontinuous (sub)sections 1103a and 1103b along the sidewall of the processing channel T. That is, in a single processing channel T, there are two (sub)sections 1103a and 1103b corresponding to each device layer. Accordingly, two memory cells may be formed subsequently.

In this example, the (sub)sections 1103a and 1103b are arranged on the upper and lower sides in the plane view of FIG. 24(c), but the present disclosure is not limited thereto, for example, the (sub)sections 1103a and 1103b may be arranged on the left and right. Alternatively, there may be more (sub)sections, such as four (sub)sections arranged in a 2×2 configuration in the plane view of FIG. 24(c).

Next, as shown in FIGS. 25(a) to 25(d), the second gate dielectric layer 1025 and the gate conductor layer 1027 may be formed as described above in combination with FIG. 9, and the annealing treatment may be performed as described above in combination with FIG. 10.

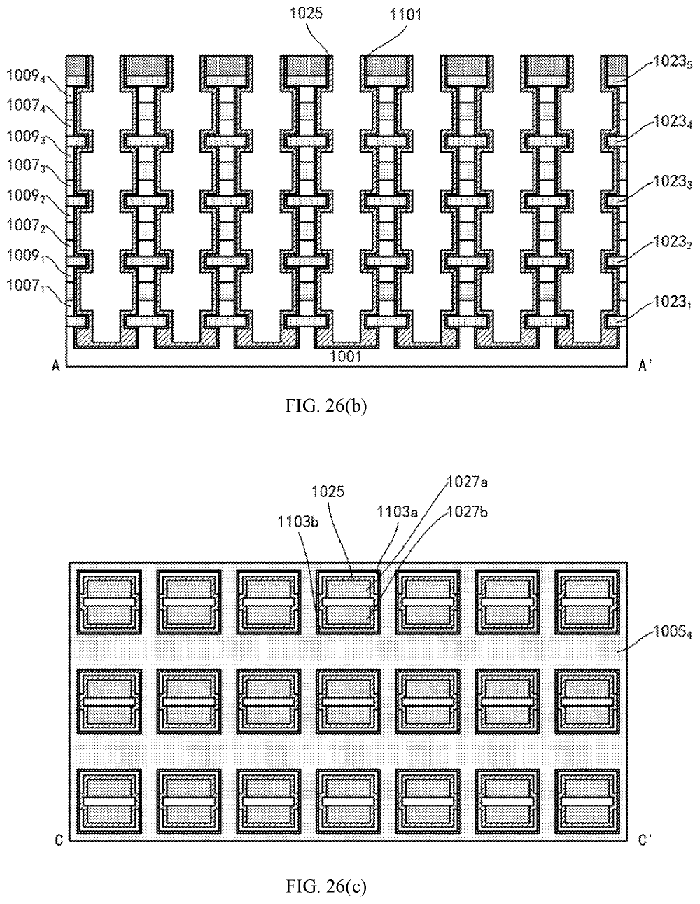

The gate conductor layer 1027 may be similarly divided into portions corresponding to each (sub)section 1103a and 1103b. For example, as shown in FIGS. 26(a) to 26(c), a photoresist 1109 may be formed. The photoresist 1109 may be patterned similarly as the photoresist 1107 to expose a portion of the gate conductor layer 1027. Such patterned photoresist 1109 may be used as an etching mask to selectively etch the gate conductor layer 1027, so as to remove the exposed portion of the gate conductor layer 1027. After that, the photoresist 1109 may be removed. Accordingly, the gate conductor layer 1027 is further divided into portions 1027a and 1027b which are discontinuous along the sidewall of the processing channel T. A corresponding memory cell is defined at a position where the portion 1027a of the gate conductor layer intersects the corresponding device layer via the memory functional layer corresponding to the (sub)section 1103a. A corresponding memory cell is defined at a position where the portion 1027b of the gate conductor layer intersects the corresponding device layer via the memory functional layer corresponding to the (sub)section 1103b. Accordingly, in a single processing channel T, each device layer may define two (or more) memory cells.

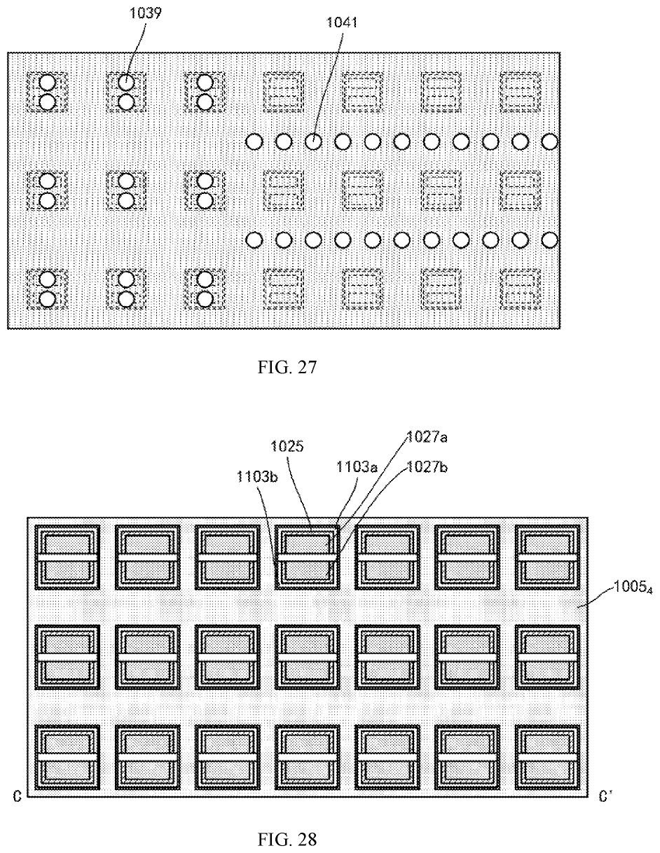

Next, the process may be performed as in the above embodiment. For example, as shown in FIG. 27, the contact portion 1039 to each of the portions 1027a and 1027b of the gate conductor layer may be formed.

In the above embodiment, the sections of the preparatory layer 1103 are further divided before forming the second gate dielectric layer. However, the present disclosure is not limited thereto. For example, as shown in FIG. 28, after the second gate dielectric layer 1025 and the gate conductor layer 1027 are formed, the sections of the gate conductor layer 1027 and the preparatory layer 1103 (and the second gate dielectric layer 1025) may be divided by selective etching using, for example, the photoresist 1109.

The memory device according to the embodiments of the present disclosure may be applied to various electronic apparatuses. For example, the memory device may store various programs, applications and data required for an operation of the electronic apparatus. The electronic apparatus may further include a processor cooperated with the memory device. For example, the processor may operate the electronic apparatus by running a program stored in the memory device. Such electronic apparatus includes, for example, a smart phone, a personal computer (PC), a tablet, an artificial intelligence device, a wearable device, or a mobile power supply, etc.

In the above description, the technical details such as patterning and etching of each layer are not described in detail. However, those skilled in the art should understand that various technical means may be employed to form a layer, a region or the like having a desired shape. In addition, in order to form the same structure, those skilled in the art may also design a method that is not completely the same as the method described above. In addition, although the respective embodiments are described above separately, this does not mean that the measures in the respective embodiments cannot be advantageously used in combination.

The embodiments of the present disclosure have been described above. However, these examples are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should fall within the scope of the present disclosure.

What is claimed is:

1. A NOR-type memory device, comprising:
a plurality of device layers stacked on a substrate, wherein each of the plurality of device layers comprises a first source/drain region and a second source/drain region at opposite ends of the device layer in a vertical direction, and a channel region between the first source/drain region and the second source/drain region in the vertical direction; and
a gate stack that extends vertically with respect to the substrate to pass through each of the plurality of device layers, wherein the gate stack comprises a gate conductor layer and a memory functional layer disposed between the gate conductor layer and the device layer, and a memory cell is defined at an intersection of the gate stack and the device layer,
wherein the memory functional layer comprises a first layer, and the first layer has a plurality of portions that correspond to the plurality of device layers respectively and are discontinuous with each other in the vertical direction.

2. The NOR-type memory device according to claim 1, wherein the plurality of portions of the first layer in the memory functional layer are self-aligned with the plurality of device layers respectively.

3. The NOR-type memory device according to claim 1, wherein the memory functional layer further comprises a second layer extending continuously in the vertical direction.

4. The NOR-type memory device according to claim 3, wherein the first layer is a conductive layer, and the second layer is an insulating layer.

5. The NOR-type memory device according to claim 1, wherein a plurality of gate stacks arranged in an array are disposed on the substrate, and
wherein a gate conductor layer of a first gate stack among the plurality of gate stacks is opposite to a gate conductor layer of a second gate stack among the plurality of gate stacks, and a memory functional layer of the first gate stack and a memory functional layer of the second gate stack extend respectively on a sidewall of the gate conductor layer of the first gate stack facing the device layer and a sidewall of the gate conductor layer of the second gate stack facing the device layer, without extending to a sidewall of the gate conductor layer of the first gate stack and a sidewall of the gate conductor layer of the second gate stack opposite to each other.

6. The NOR-type memory device according to claim 1, further comprising:
a plurality of isolation layers, wherein the plurality of device layers and the plurality of isolation layers are alternately stacked on the substrate, and each of the plurality of device layers is between isolation layers in the vertical direction,
wherein each of the plurality of portions of the first layer of the memory functional layer is located between isolation layers in the vertical direction.

7. The NOR-type memory device according to claim 6, wherein each of the plurality of device layers and the plurality of isolation layers has a sidewall opposite to the gate stack, and
wherein the sidewall of the isolation layer is protruded transversely with respect to the sidewall of the device layer towards the gate stack, and each of the plurality of portions of the first layer of the memory functional layer is disposed in a recess defined by a sidewall of a corresponding device layer, the isolation layer above the corresponding device layer, and the isolation layer below the corresponding device layer.

8. The NOR-type memory device according to claim 6, wherein a hole extending vertically is provided in the plurality of device layers and the plurality of isolation layers, and the gate stack is formed in the hole, and
wherein a portion of the hole corresponding to the device layer is expanded transversely with respect to a portion of the hole corresponding to the isolation layer, and each of the plurality of portions of the first layer of the memory functional layer is disposed in a portion of the hole corresponding to a corresponding device layer.

9. The NOR-type memory device according to claim 8, wherein each of the plurality of portions of the first layer of the memory functional layer extends on a sidewall of the corresponding device layer in the hole, a top surface of the isolation layer below the corresponding device layer in the hole, and a bottom surface of the isolation layer above the corresponding device layer in the hole.

10. The NOR-type memory device according to claim 8, wherein each of the plurality of portions of the first layer of the memory functional layer extends on a sidewall of the corresponding device layer in the hole, without extending to a top surface of the isolation layer below the corresponding device layer in the hole and a bottom surface of the isolation layer above the corresponding device layer in the hole.

11. The NOR-type memory device according to claim 8, wherein a plurality of gate stacks are disposed in a single hole, and
wherein the memory functional layer is disposed along a sidewall of the hole without extending to a position between the plurality of gate stacks.

12. The NOR-type memory device according to claim 6, wherein the isolation layer contains a dopant identical to a dopant in the first source/drain region and a dopant in the second source/drain region.

13. The NOR-type memory device according to claim 12, wherein a concentration of the dopant in the isolation layer is equal to or higher than a doping concentration in the first source/drain region and a doping concentration in the second source/drain region.

14. The NOR-type memory device according to claim 6, wherein a doping concentration in the first source/drain region decreases towards the channel region in the vertical direction, and a doping concentration in the second source/drain region decreases towards the channel region in the vertical direction.

15. The NOR-type memory device according to claim 1, wherein the device layer comprises:
a base layer; and
a semiconductor layer on a sidewall of the base layer facing the gate stack, wherein the semiconductor layer is in form of a nanosheet, and the channel region is substantially formed in the semiconductor layer.

16. The NOR-type memory device according to claim 1, wherein the device layer comprises a single crystal semiconductor material.

17. The NOR-type memory device according to claim 1, wherein the memory functional layer comprises a floating gate layer or a charge trapping layer as the first layer.

18. A method of manufacturing a NOR-type memory device, comprising:
alternately disposing a plurality of device layers and a plurality of isolation layers on a substrate, so that each of the plurality of device layers is located between isolation layers in a vertical direction;
forming a processing channel that extends vertically with respect to the substrate to pass through each of the plurality of device layers and each of the plurality of isolation layers;
selectively etching the device layer through the processing channel, so that the device layer is transversely recessed with respect to the isolation layer;
forming a memory functional layer on a sidewall of the processing channel, wherein the memory functional layer comprises a first layer, and the first layer has a plurality of portions, wherein each portion of the first layer is located between respective isolations layers and the plurality of portions are discontinuous with each other in the vertical direction; and
forming a gate conductor layer in the processing channel with the sidewall on which the memory functional layer is formed, wherein a corresponding memory cell is defined at a position where the gate conductor layer intersects a corresponding device layer via the memory functional layer.

19. The method according to claim 18, wherein the isolation layer contains a dopant, and the method further comprises:
driving the dopant from the isolation layer to opposite ends of the device layer by annealing.

20. The method according to claim 18, further comprising:
epitaxially growing a semiconductor layer on a sidewall of the device layer facing the processing channel, wherein the semiconductor layer is located between respective isolation layers,
wherein the memory functional layer is formed on the semiconductor layer.

21. The method according to claim 18, wherein forming the memory functional layer comprises:
forming a preparatory first layer on the sidewall of the processing channel; and
etching a portion of the preparatory first layer on a sidewall of the isolation layer facing the processing channel, so as to form the first layer having the plurality of portions discontinuous with each other in the vertical direction, wherein each of the plurality of portions of the first layer is left in the recess of respective device layer with respect to the isolation layer.

22. The method according to claim 21, further comprising:
forming a protective layer on the preparatory first layer;
etching a portion of the protective layer on the sidewall of the isolation layer facing the processing channel, so as to expose a portion of the preparatory first layer below the protective layer for etching,
wherein after etching the portion of the preparatory first layer on the sidewall of the isolation layer facing the processing channel, the method further comprises:
further etching the preparatory first layer, so that the plurality of portions of the first layer only extend on a sidewall of the device layer facing the processing channel; and
removing the protective layer.

23. The method according to claim 18, wherein disposing the plurality of device layers and the plurality of isolation layers comprises: alternately forming the plurality of device layers and a plurality of sacrificial layers on the substrate by epitaxial growth, and
wherein the method further comprises: replacing the plurality of sacrificial layers by the plurality of isolation layers via the processing channel.

24. The method according to claim 18, further comprising:
epitaxially growing a semiconductor layer on a sidewall of the device layer facing the processing channel, wherein the semiconductor layer is located between respective isolation layers, and the memory functional layer is formed on the semiconductor layer,
wherein the annealing causes a dopant in the device layer to diffuse transversely into the semiconductor layer.

25. The method according to claim 24, wherein the transverse diffusion causes a non-uniform doping distribution in a middle portion of the semiconductor layer: a doping concentration of the semiconductor layer on a side of the semiconductor layer close to the device layer is higher than a doping concentration of the semiconductor layer on a side of the semiconductor layer away from the device layer.

26. The method according to claim 18, further comprising:
further dividing each of the plurality of portions of the first layer between respective isolations layers into a plurality of sub-portions that are discontinuous with each other along the sidewall of the processing channel; and
dividing the gate conductor layer into a plurality of portions that are discontinuous with each other along the sidewall of the processing channel and correspond to the plurality of sub-portions respectively.

27. An electronic apparatus comprising the NOR-type memory device according to claim 1.

28. The electronic apparatus according to claim 27, wherein the electronic apparatus comprises a smart phone, a computer, a tablet, an artificial intelligence device, a wearable device, or a mobile power supply.
